(19) United States
(12) Patent Application Publication
(10) Pub. No.: US 2026/0247992 A1
(43) Pub. Date: Aug. 20, 2026

(54) METHOD FOR PRODUCING AN SMD SEMICONDUCTOR ASSEMBLY POPULATED WITH A CIRCUIT CARRIER, SMD SEMICONDUCTOR ASSEMBLY, AND CIRCUIT CARRIER

(71) Applicant: iCuTech - Anlagenbau GmbH, Nürnberg (DE)

(72) Inventors: Christian Göbl, Nürnberg (DE); Jürgen Steger, Hiltpoltstein (DE)

(21) Appl. No.: 19/161,172

(22) PCT Filed: Mar. 12, 2024
(86) PCT No.: PCT/EP2024/056513

§ 371 Date: Aug. 29, 2025

(30) Foreign Application Priority Data
Apr. 24, 2023 (DE) 10 2023 110 343.1

(51) Int. Cl. H10W 70/00; H10W 74/01

(52) U.S. Cl. CPC H10W 70/099; H10W 74/012

(57) ABSTRACT

The invention relates to a method for producing an SMD semiconductor assembly populated with a circuit carrier (100), said method comprising: providing an SMD circuit carrier (1) furnished with contact points (3) of a conductor track structure (2a) and with insulation, preferably an IMS substrate or lead frame; providing a circuit carrier (100) with a first main side (102) at least partially furnished with an electric conductor and a second main side (103) which is opposite the first main side (102) and is at least partially furnished with the electric conductor, wherein in the circuit carrier (100) at least one blind hole (108), furnished with the electric conductor, is provided with a blind hole bottom (104), and the blind hole bottom (104) is formed, preferably exclusively, by at least one layer of the electric conductor; positioning the blind hole bottom (104) of the circuit carrier (100) in bearing contact at a contact point (3) of the SMD circuit carrier (1) and establishing an electric contact by melting the blind hole bottom (104) of the circuit carrier (100) and of the contact point (3) of the SMD circuit carrier (1) by means of laser welding.

### PRINTED STATE OF THE ART

The present invention relates, on the one hand, to a method for producing an SMD semiconductor component assembly equipped with a circuit carrier. The invention further relates to an SMD semiconductor component assembly and a circuit carrier for use in the aforementioned method.

DE 40 02 326 A1 discloses a method and a device for perforating a printed circuit board. To produce a circuit board with a connection hole, a guide hole is first created with a drill and then the synthetic resin material is removed down to the copper foil on the underside using a laser. The connection hole thus formed is then coated with a copper layer and the wiring patterns are formed by etching.

DE 10 2014 209 411 A1 relates to an electronic control module for a transmission control and a method for its production. In this case, the connections of an electrical component on the side of the circuit board facing the component must be contacted via a mating connection section of a press contact previously pressed into an opening in the circuit board. The connections of the component are welded to the mating connection section of the press contact using a laser. The opening in the circuit board that accommodates the press contact must be covered by a plastic frame to protect it from contamination. The manufacture of the electrical component is complex and costly. Object of the present invention.

### OBJECT OF THE PRESENT INVENTION

The object of the present invention is to enable the assembly of an SMD circuit carrier with a circuit carrier in a reliable and cost-effective manner while taking up little installation space.

### SOLUTION TO THE TASK

The problem is solved with respect to the manufacturing method by claim 1, with respect to the SMD semiconductor component assembly by claim 10, and with respect to the circuit carrier by claim 17. Advantageous embodiments of the present invention are claimed in the respective subclaims.

The method according to the invention comprises the steps:
Providing an SMD circuit carrier provided with contact points of a preferably foil-like or layered conductor track structure and an insulation, preferably in the form of an IMS substrate or leadframe,
Providing a circuit carrier with a first main side at least partially coated with an electrical conductor and a second main side opposite the first main side and at least partially coated with an electrical conductor, wherein at least one blind hole coated with the electrical conductor with a blind hole base is provided in the circuit carrier, and the blind hole base is formed, preferably exclusively, by at least one layer of the electrical conductor,
Positioning the blind hole base of the circuit carrier in contact with a contact point of the SMD circuit carrier, and
electrical contact by melting the blind hole base of the circuit carrier and the contact point of the SMD circuit carrier by means of laser welding. The method according to the invention makes it possible to weld an SMD circuit carrier to a circuit carrier without soldering technology, i.e. without fluxers, radiant heaters and soldering waves, using clean technology with a reliable
current-carrying electrical. This allows reliable fitting of an SMD circuit carrier, preferably in the form of an I MS substrate or a lead frame, with a circuit carrier in a particularly cost-effective manner. In addition, a connection can be made in the smallest possible space, as no additional connecting elements are used. The elimination of additional connecting elements increases the quality and reliability of the connection.

The SMD circuit carrier and the circuit carrier can be additionally glued together after the laser welding process. This can further increase reliability.

Preferably, the SMD circuit carrier and circuit carrier are bonded together using a so-called underfilling with a flowable adhesive. Using underfilling, gaps between SMD circuit carrier and circuit carrier can be filled with adhesive.

Alternatively or additionally, the circuit carrier can be attached to the SMD circuit carrier by means of a mechanical holder, preferably a holding plate. The circuit carrier is clamped between the holder and the SMD circuit carrier. Preferably, this also allows the respective power semiconductor component 4 to be electrically and thermally contacted at its coating 6, forming a pressure contact on the SMD circuit carrier 1. Accordingly, laser welding is only required in the area of the connecting elements. In the area of the laser welding points, the holder can have openings for the laser beam. This enables laser welding with the holding plate already pre-assembled.

The method according to the invention advantageously allows a circuit carrier already pre-equipped with electrical and/or electronic components to be melted by melting the blind hole base of the circuit carrier and the
contact point of the SMD circuit carrier to be electrically contacted by means of laser welding. Due to the method according to the invention, such circuit carriers can therefore advantageously be kept ready as pre-completed assembly modules and the SMD circuit carrier can thus be used, for example B. can be contacted or assembled in one process step.

The SMD circuit carrier can be additionally equipped with at least one power semiconductor component on the side to be equipped with the circuit carrier. Power semiconductor components are in particular components with a high current carrying capacity (e.g. B. designed for a minimum current of 100 A). Due to the higher currents in these components, the contacts to heat up more. An SMD semiconductor component assembly comprising such power semiconductor components can be supplemented with a circuit carrier fitted with electrical and/or electronic components using the method according to the invention. For example, the electrical and/or electronic components of the circuit carrier are processors or microchips for electronic control and/or sensors and/or data acquisition (data loggers) and/or data transmission modules such as B. radio modules or data interfaces. Such functionalities can be combined completely or in part in microchips with which the circuit carrier can be equipped.

In particular, at least one power semiconductor component can have connection elements which are positioned in contact with a contact point of the SMD circuit carrier, wherein the connection elements are also electrically contacted with the associated contact point by means of laser welding. Thus, both the at least one power semiconductor component and the circuit carrier on the component side of the SMD circuit carrier can be electrically contacted by means of laser welding.

For the welding process, the laser beam can preferably scan the surface of the SMD semiconductor component using a search optic, the laser can be optically to the respective welding positions and successively carry out the laser welding at the points identified by the search optics.

It is particularly advantageous from a production perspective if the electrical contacting of the blind hole base of the circuit carrier with the contact point of the SMD circuit carrier, as well as the electrical contacting of the connection elements of the at least one power semiconductor component with the associated contact point of the SMD circuit carrier is carried out by means of laser welding. In this way, both power semiconductor components and circuit carriers, which in particular may already be pre-equipped with electrical and/or electronic components, can be successively and permanently electrically contacted in one process step by means of the laser.

The method according to the invention can also be used advantageously when the SMD circuit carrier has a cooler, e.g., on its side opposite the side to be equipped with the circuit carrier. B. in the form of a heat-dissipating metal layer or a cooling structure or an active cooling device (e.g. B. cooling by a cooling fluid).

An IMS substrate is a metal substrate (preferably an aluminum substrate) on which there is insulation in the form of a layer of an insulator or a dielectric, on which in turn the conductor track structure (in particular in the form of a metal foil, preferably a copper foil) is located. In addition to ensuring mechanical stability, the metal substrate also serves to dissipate heat, e.g. B. to a cooler. A leadframe is a e.g. B. stamped metallic conductor carrier in the form of a frame mounted on an insulating carrier or in a housing.

The present invention further relates to an SMD semiconductor component assembly comprising
an SMD circuit carrier provided with contact points of a conductor track structure and an insulator, preferably in the form of an IMS substrate or leadframe, with a first main side and a second main side,
at least one circuit carrier equipped with electrical and/or electronic components, with which the first main side of the SMD circuit carrier is equipped,
wherein the circuit carrier has at least one blind hole with a blind hole base, wherein the blind hole base is formed, preferably exclusively, by at least one layer of an electrical conductor, and
wherein an electrical contact of the circuit carrier to the SMD circuit carrier is provided in the form of a laser welded connection in the blind hole base.

Preferably, the first main side of the SMD circuit carrier is additionally equipped with at least one power semiconductor component.

Because an electrical contact of the at least one power semiconductor component with the first main side of the SMD circuit carrier is provided in the form of a laser welded connection on the connection elements of the power semiconductor component, the assembly or electrical contact of the SMD circuit carrier with the at least one power semiconductor component and with the circuit carrier can be carried out in a single process step.

The electrical contacting of the at least one power semiconductor component with the first main side of the SMD circuit carrier in the form of a laser welded connection is preferably provided on the connection elements (connection legs) of the power semiconductor component.

To secure the circuit carrier, an adhesive layer, preferably in the form of an underfill adhesive layer, can be provided between the SMD circuit carrier and the circuit carrier. The material of the adhesive is preferably an insulator or a dielectric.

Alternatively or additionally, the circuit carrier, preferably including the power semiconductor components, can be clamped between a holder, preferably a holding plate, and the SMD circuit carrier on the SMD circuit carrier.

According to an expedient embodiment, the SMD circuit carrier has a cooler, in particular in the form of a cooling structure and/or a metal layer and/or an active cooling device (e.g. B. cooling by a cooling fluid),

The SMD circuit carrier is preferably an IMS substrate. An IMS substrate is a metal substrate (preferably an aluminum substrate) on which there is a layer of an insulator or a dielectric, on which there is in turn a conductor structure. The metal substrate serves to dissipate heat and therefore provides a heat-conducting contact to a cooler.

The present invention further relates to a circuit carrier having at least one blind hole with a blind hole base made of conductive material, in particular for use in a method according to claims 1 to 9. According to the invention, the circuit carrier is designed as an assembly unit pre-equipped with electrical and/or electronic components for the laser welding process.

### DESCRIPTION OF THE INVENTION USING EXEMPLARY EMBODIMENTS

Appropriate embodiments of the present invention are explained in more detail using examples in the drawing figures. For the sake of clarity, recurring features are only provided with a reference symbol only once.

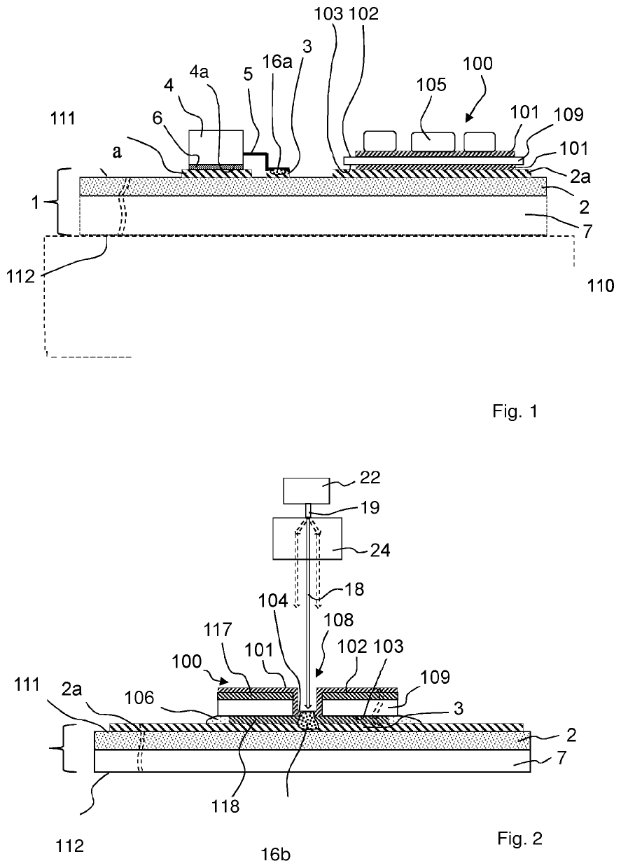

FIG. 1 is a highly simplified schematic representation of an example of an SMD semiconductor component assembly according to the present invention;

FIG. 2 is a highly simplified schematic representation of the electrical contacting of a circuit carrier on an SMD circuit carrier by means of laser welding for the production of an SMD semiconductor component assembly according to FIG. 1;

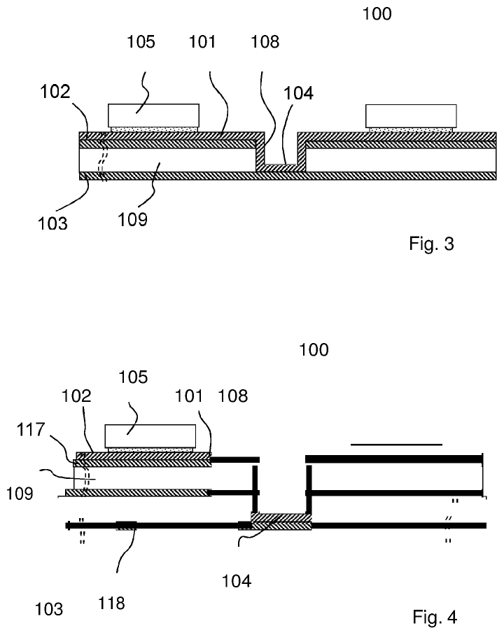

FIG. 3 shows an example of a circuit carrier as an assembly unit pre-equipped with electrical and/or electronic components for electronic contacting according to FIG. 2;

FIG. 4 shows an alternative example of a circuit carrier designed as a multilayer as an assembly unit pre-assembled with electrical and/or electronic components for electronic contacting with an SMD circuit carrier by means of laser welding;

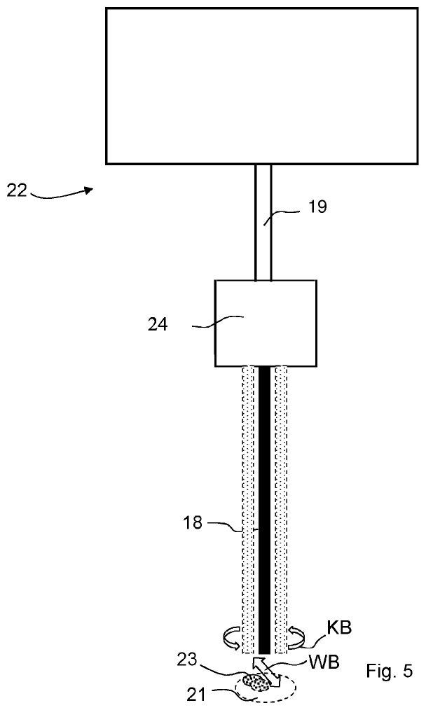

FIG. 5 is a highly simplified schematic representation of the laser during the execution of the laser welding connection according to FIG. 2;

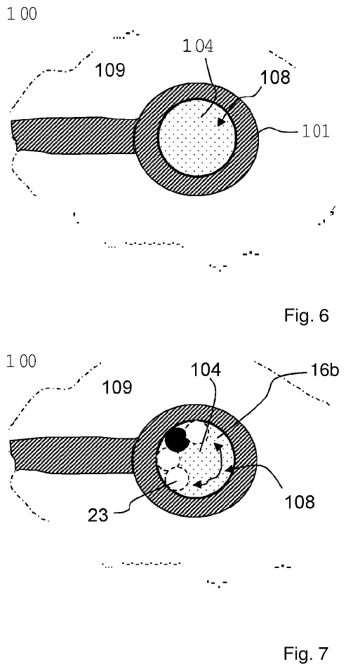

FIG. 6 is a plan view of the top side of the circuit carrier according to FIG. 3 in the area of the blind hole before laser welding is carried out;

FIG. 7 is a plan view of the top side of the circuit carrier according to FIG. 3 in the region of the blind hole during the laser welding process;

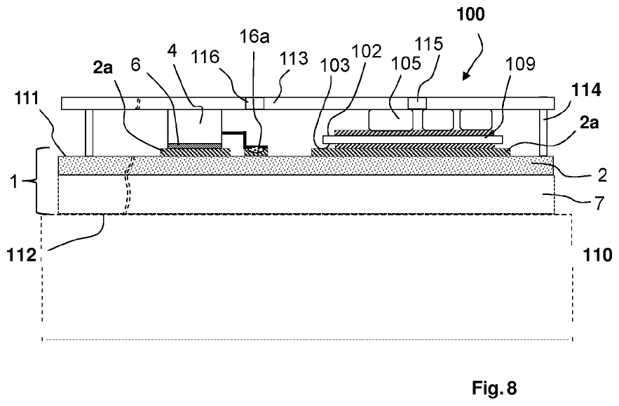

FIG. 8 is a highly simplified schematic representation of an alternative example of an SMD semiconductor component assembly according to the present invention; and

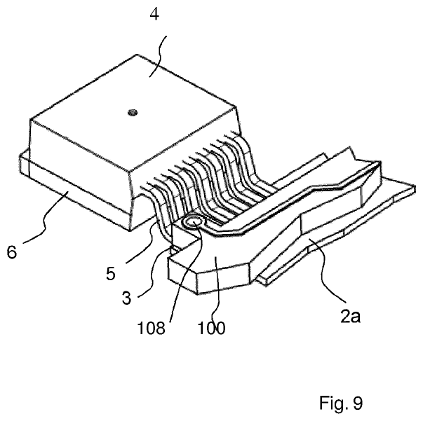

FIG. 9 is a simplified perspective view of further example of a connection of a circuit carrier according to the invention, in which the connection has been made by laser welding in the blind hole of the circuit carrier to a connection element of a power semiconductor component of the SMD circuit carrier.

Reference number 1 in FIG. 1 denotes a layered SMD circuit carrier. The SMD circuit carrier 1 comprises a base body 7 and a conductor track structure 2a provided on the component side of the SMD circuit carrier 1. In between there is a layer of an insulator 2 or dielectric. The conductor track structure 2a is preferably a copper layer, in particular in the form of an applied and structured copper foil. A corresponding SMD circuit carrier 1 is also referred to as IMS (Insulated Metal Substrate). The base body 7 is a metal-based substrate, in particular aluminum or copper-based. The base body 7 has good mechanical stability and high thermal conductivity and is therefore suitable for serve as a cooler for the SMD semiconductor component assembly or at least (as shown in FIG. 1) to establish a thermally conductive contact with a cooler 110 shown in dashed lines.

On the component side of the SMD circuit carrier 1, at least one, preferably a plurality of power semiconductor components 4 are electrically contacted. The electrical contact is made, on the one hand, via an electrically and thermally conductive base surface 4a of the power semiconductor component 4 with a contact point of the conductor track structure 2a of the SMD circuit carrier 1. The electrically and thermally conductive base surface 4a can be provided with a coating 6 made of silver or a silver alloy. On the other hand, the connection elements 5 (connection legs) of the power semiconductor component 4 are electrically contacted with a contact point 3 of the conductor track structure 2a by means of a laser weld connection 16a. In addition, the power semiconductor-component 4 can be mechanically fixed to the SMD circuit carrier 1 with a certain contact pressure via a holding part positioned on the top side of the component and connected to the SMD circuit carrier 1 (not shown in FIG. 1).

The type of power semiconductor component 4 is particularly a component with a high current carrying capacity (e.g. B. designed for a minimum current of 100 A). Due to the higher currents in such power semiconductor components, the contacts heat up more. In this context, the laser welded connection 16a has a particularly favorable effect in terms of its current carrying capacity compared to a soldered connection.

Such power semiconductor components can be used in particular to control electrical machines, e.g. B. brushless DC motors etc.

In addition, the SMD circuit carrier 1 of FIG. 1 is equipped on its component side with at least one circuit carrier 100, which in turn is equipped with electrical and/or electronic components 105. The electronic components may in particular be processors or microchips for electronic control and/or data acquisition (data loggers) and/or data transmission modules or communication technology, such as B. radio modules, and/or data interfaces. Such functionalities can be combined completely or partially in microchips with which the circuit carrier 100 can be equipped. For example, the electrical component 105 in FIG. 1 may be a processor for electronic control, a data logger or a radio module.

The circuit carrier 100 comprises an insulator layer 109 with a first main side 102, which is the component side of the circuit carrier 100, and a second main side 103 opposite the first main side 102. On both main sides 102 and 103 there is a preferably structured electrical conductor, for example in the form of structured copper layers, are provided. A more detailed representation of the layer sequence can be seen in FIGS. 2 to 4.

The SMD circuit carrier 1 forms an SMD semiconductor component assembly with the power semiconductor components 4 electrically contacted on its component side and the at least one circuit carrier 100. Such an SMD semiconductor component assembly is located on the cooler 110, which is shown schematically in FIG. 1 only in dashed lines and in a highly simplified manner.

FIG. 2 shows a detailed representation of the electrical contacting and fastening of the circuit carrier 100 of the SMD semiconductor component assembly of FIG. 1 on the SMD circuit carrier 1. The electrical contacting of the circuit carrier 100 with the SMD circuit carrier 1 is carried out in the area of a blind hole 108 of the circuit carrier 100 by means of laser welding. The blind hole 108 is a blind hole whose blind hole bottom 104 is formed, preferably exclusively, by a layer of the electrical conductor in the form of a galvanization layer 101 and the underside metallization 118 of the circuit carrier 100 (also called “via metallization”). This means that no material of the insulator layer 109 is located in the area of the blind hole bottom 104. During the laser welding, only the blind hole base 104 consisting of the electrical conductor or the relevant contact point of the conductor track structure 2a must be melted, resulting in the laser weld connection 16b. Reference number 117 denotes the top-side metallization of the circuit carrier 100, on which the electroplating layer 101 is also located.

For the welding process, a laser equipped with a scanner 24, preferably a fiber laser 22, is preferably used. The scanner 24 detects the relevant contact points to be welded and can align the laser beam 18 to them according to the positions of the contact points to be welded. The laser beam always preferably hits the contact point to be welded at a 90° angle. The respective alignment of laser 22 takes place in scanner 24. This is simplified and schematically indicated in FIG. 2 by the additional dashed laser beams. This allows individual contact points to be welded, located in different blind holes, to be successively exposed to the laser beam, preferably at a 90° angle.

The laser light is guided by the laser via a glass fiber 19 and the laser beam 18 is directed to the respective welding point via scanner 24 and the optics located therein.

The electrical contacting of the blind hole base 104 of the circuit carrier 100 with the contact point 3 of the SMD circuit carrier 1 as well as the electrical contacting of the connection elements 5 of the at least one power semiconductor component 4 with the associated contact point 3 of the SMD circuit carrier 1 can thus advantageously be carried out by means of laser welding. The laser beam 18 is successively optically aligned to the respective welding position using its search optics (scanner 24). This, the SMD circuit carrier 1 can advantageously be electrically contacted in one process step both with the power semiconductor component 4 and with a circuit carrier 100 comprising electronic components 105 without complex soldering technology.

In order to further increase the mechanical strength of the circuit carrier 100 on the SMD circuit carrier 1, the SMD circuit carrier 1 and the circuit carrier 100 are glued together, preferably after laser welding.

For this purpose, an adhesive 106 that is flowable in its initial state is used. This penetrates in the form of an underfill into the gap between the circuit carrier 100 and the SMD circuit carrier 1 and ensures mechanical cohesion after curing.

The particular advantage of the present invention is that pre-assembled circuit carriers 100 can be kept ready and can be electrically contacted with an SMD circuit carrier 1 in the manner described above.

FIG. 3 shows an example of such a circuit carrier 100 pre-assembled with electrical and/or electronic components 105, which can be used as an assembly unit for the laser welding process.

As can be seen from FIG. 3, the blind hole bottom 104 is formed exclusively by the electrical conductor. The electrical conductor can also have several layers (e.g. B. as shown in FIG. 3, two layers, namely the electroplating layer 101 and the layer of the underside metallization 118). A galvanization layer on the underside, not shown in the figures, may also be provided. In this case, this layer can form an additional layer of the electrical conductor.

The invention is not limited to circuit carriers 100 with only one insulator layer 109, but can also be used with circuit carriers 100 which have a plurality of insulator layers 109 separated by a further metallization 119, as is shown by way of example in FIG. 4.

FIG. 5 shows, in a highly simplified schematic representation, the mode of operation of the laser to be used to produce the laser weld connection 16b. This is preferably a so-called fiber laser 22, in which the laser beam 18 is provided via a fiber optic cable 19. The scanner 24 can be used to move the laser beam 18 according to the required application. The scanner 24 can ensure that the laser beam 18 performs, for example, a circular movement KB around a central axis, as shown in FIG. 5. Alternatively or additionally, the laser beam 18 can also perform a wobbling movement WB, as also shown in FIG. 5.

FIG. 5 shows an example of a coupling surface 23 of the laser beam 18 in a snapshot during the circular movement KB and during the wobbling movement WB. The laser is preferably an IR laser.

The focus spot of the laser has a diameter in the range of 20-50 μm, in particular 30-40 μm. The melting region 21 created by the laser beam 18 is at least substantially continuous, for example point-shaped or circular. The diameter of the melting region 21 is in a range of 60-100 μm, preferably 70-90 μm.

FIG. 6 shows the blind hole bottom 104 of the circuit carrier 100 before the laser welding process. In contrast, FIG. 7 shows a snapshot during welding, showing the coupling surfaces 23 of the laser beam 18 changing during the welding process, for example B. during a circular movement KB. The circular movement KB can be superimposed by a wobbling movement WB. This can create a point-shaped or circular melting area 21.

Alternatively, or in addition to the bonding of the circuit carrier 100 using adhesive 106 (see FIG. 2), the circuit carrier 100 according to the embodiment of FIG. 8 can be fastened or clamped to the SMD circuit carrier 1 by means of a mechanical holder, preferably by means of a holding plate 113. The circuit carrier 100 is e.g. B. clamped between the holder and the SMD circuit carrier using retaining screws 114 or retaining pins. In the area of the laser welding points 16a for the power semiconductor components 4, i.e. in the area of the respective connection elements 5, or in the area of the laser welding points 16b for the circuit carrier 100, i.e. in the area of the respective blind holes 108, the holder can each have through opening 115 and 116 for the laser beam 18. This enables laser welding with the retaining plate 113 already pre-assembled.

FIG. 9 shows another possibility of connecting a circuit carrier 100 to a power semiconductor component 4 of an SMD circuit carrier 1. For the sake of clarity, FIG. 9 only shows a part of the circuit carrier 100, the conductor track structure 2a as part of the SMD circuit carrier 1 and a power semiconductor component 4 as part of the SMD circuit carrier located underneath. Of the SMD circuit carrier 1, only the conductor track structure 2a is partially shown. The design of the blind hole corresponds to the design of the blind hole in FIG. 3 or 4.

In this embodiment, the laser welding takes place via the blind hole 108 in the area of a connecting element 5 or connection pin of the power semiconductor component 4. For this purpose, the circuit carrier 100 with its blind hole 108 is brought into the position of a connection element 5 located underneath. The circuit carrier 100 is connected directly to the connection element 5 by laser welding via the blind hole bottom of the blind hole 108. It is a particularly space-saving solution, as there is no need for an island specifically provided for contacting the SMD circuit carrier as a contact point. Accordingly, the cooler can also be dimensioned smaller in its surface area.

The present invention makes it possible to manufacture SMD semiconductor component assemblies with high reliability and current carrying capacity and small size with a comparatively simple process sequence. The present invention therefore represents a very significant contribution to the relevant field of technology.

### REFERENCE MARK LIST

1 SMD circuit carrier
2 Insulator
2a Conductor track structure
3 Contact point
4 Power semiconductor component
4a Electrically conductive base surface
5 Connecting element
6 Coating
7 Basic bodies
8 Welding windows
9 Carrier part
10 SMD circuit carrier
16a Laser welding connection
16b Laser welding connection
18 Laser beam
19 Fiber optic
21 Melting area
22 Fiber laser
23 Coupling area
24 Scanner
100 Circuit carrier
101 Electroplating layer
102 First main page of the circuit boards
103 Second main page of the circuit boards
104 Blind hole bottom
105 Electrical component
106 Adhesive
108 Blind hole
109 Insulator layer
110 Cooler
111 First main page of the SMD circuit carrier
112 Second main page of the SMD circuit carrier
113 Holding plate
114 Retaining screw
115 Passage opening
116 Passage opening
117 Metallization
118 Metallization
119 Metallization
KB Circular movement
WB Wobbling movement

1. Method for producing an SMD semiconductor component assembly equipped with a circuit carrier, comprising:
Providing an SMD circuit carrier, preferably an IMS substrate or leadframe, provided with contact points of a conductor track structure and an insulation,
Providing a circuit carrier with a first main side at least partially provided with an electrical conductor and a second main side opposite the first main side and at least partially provided with the electrical conductor, wherein at least one blind hole provided with the electrical conductor and having a blind hole base is provided in the circuit carrier, and the blind hole base is formed, preferably exclusively, by at least one layer of the electrical conductor,
Positioning the blind hole base of the circuit carrier at a contact point of the SMD circuit carrier and electrical contacting by melting the blind hole base of the circuit carrier and the contact point of the SMD circuit carrier by means of laser welding.

2. Method according to claim 1, characterized in that the SMD circuit carrier and the circuit carrier are glued together after laser welding.

3. Method according to claim 2, characterized in that the bonding of SMD circuit carrier and circuit carrier is carried out by underfilling with an adhesive which is flowable in the initial state.

4. Method according claim 1, characterized in that the circuit carrier is fastened to the SMD circuit carrier by means of a mechanical holder, preferably a holding plate.

5. Method according claim 1, characterized in that a circuit carrier already pre-equipped with electrical and/or electronic components is electrically contacted by melting the blind hole bottom of the circuit carrier and the contact point of the SMD circuit carrier by means of laser welding.

6. Method according claim 1, characterized in that the SMD circuit carrier is equipped with at least one power semiconductor component on its side to be equipped with the circuit carrier.

7. Method according claim 1, characterized in that the at least one power semiconductor component has connection elements, the connection elements are positioned in contact with a contact point of the SMD circuit carrier, and the connection elements are electrically contacted with the associated contact point by melting by means of laser welding.

8. Method according to claim 7, characterized in that electrical contact is made between the blind hole bottom of the circuit carrier and the contact point of the SMD circuit carrier via a connection element of the power semiconductor component located therebetween.

9. Method according claim 1, characterized in that the electrical contacting of the blind hole bottom of the circuit carrier with the contact point of the SMD circuit carrier and the electrical contacting of the connection elements of the at least one power semiconductor component with the associated contact point of the SMD circuit carrier is carried out by means of laser welding in that the laser beam is successively optically aligned to the respective welding position by means of a search optics (scanner).

10. Method according claim 1, characterized in that the SMD circuit carrier has a cooler on its side opposite the side to be equipped with the circuit carrier.

11. SMD semiconductor component assembly, comprising an SMD circuit carrier, preferably an IMS substrate or leadframe, provided with contact points of a conductor track structure and an insulator, with a first main side and a second main side, at least one circuit carrier equipped with electrical and/or electronic components, with which the first main side of the SMD circuit carrier is also equipped, characterized in that the circuit carrier has at least one blind hole with a blind hole bottom, wherein the blind hole bottom is formed, preferably exclusively, by at least one layer of an electrical conductor, and an electrical contact between the circuit board and the SMD circuit carrier is provided in the form of a laser-welded connection in the blind hole bottom.

12. SMD semiconductor component assembly according to claim 11, characterized in that the first main side of the SMD circuit carrier is additionally equipped with at least one power semiconductor component.

13. SMD semiconductor component assembly according to claim 11, characterized in that an electrical contacting of the at least one power semiconductor component with the first main side of the SMD circuit carrier is provided in the form of a laser welded connection on the connection elements of the power semiconductor component.

14. SMD semiconductor component assembly according to claim 11, characterized in that an adhesive layer, preferably in the form of an underfill adhesive layer, is located between the SMD circuit carrier and the circuit carrier for fastening the circuit carrier.

15. SMD semiconductor component assembly according to claim 11, characterized in that the circuit carrier is clamped between a holder, preferably a holding plate, and the SMD circuit carrier.

16. SMD semiconductor component assembly according to claim 11, characterized in that the SMD circuit carrier has a cooler, in particular in the form of a cooling structure and/or a metal layer and/or an active cooling device, on its side opposite the side to be equipped with the circuit carrier.

17. SMD semiconductor component assembly according to claim 11, characterized in that an I MS substrate is provided as the SMD circuit carrier.

18. Circuit carrier, in particular for use in a method according to claim 1, with at least one blind hole with a blind hole base made of conductive, preferably exclusively conductive material, characterized in that the circuit carrier is designed as an assembly unit pre-equipped with electrical and/or electronic components for the laser welding process.
